(19) United States
(12) Patent Application Publication
(10) Pub. No.: US 2019/0172991 A1
(43) Pub. Date: Jun. 6, 2019

(54) METHOD FOR MAKING METAL-CERAMIC LAMINATE HEAT-DISSIPATING SUBSTRATE, AND ELECTRONIC DEVICE AND LED COMPRISING THE HEAT-DISSIPATING SUBSTRATE

(71) Applicant: Yi-Jhen LEE, Mingjian Township (TW)

(72) Inventor: Yi-Jhen LEE, Mingjian Township (TW)

(21) Appl. No.: 16/207,900

(22) Filed: Dec. 3, 2018

(30) Foreign Application Priority Data
Dec. 6, 2017 (TW) 106142809

(51) Int. Cl. H01L 33/64; H01L 21/48; B28B 11/24; B28B 11/12; B33Y 10/00; B33Y 80/00

(52) U.S. Cl. CPC H01L 33/642; H01L 21/4871; B28B 11/243; H01L 2933/0075; B33Y 10/00; B33Y 80/00; B28B 11/12

(57) ABSTRACT

The present invention provides a method for making a metal-ceramic laminate heat-dissipating substrate, comprising the steps of: providing a metal base layer; forming a not-yet-sintered ceramic layer on a surface of the metal base layer; and forming a metal line on a surface of the not-yet-sintered ceramic layer, and then performing a sintering process. The method of the present invention for making the metal-ceramic laminate heat-dissipating substrate has the advantages of producing heat-dissipating substrate with high bonding strength between the metal lines and the ceramic layer, and lowering the material cost of the heat-dissipating substrate.

### BACKGROUND OF THE INVENTION

### 1. Technical Field

The present invention relates to a method for making a metal-ceramic laminate heat-dissipating substrate. More particularly, the invention relates to a method for making a metal-ceramic laminate heat-dissipating substrate for use in light-emitting diodes.

### 2. Description of Related Art

To provide highly efficient heat dissipation, heat-dissipating substrates have progressed from those with a plastic main body, such as metal-core printed circuit boards (MCPCBs), to those with a ceramic main body. Currently, the common ceramic heat-dissipating substrate includes low-temperature co-fired ceramic (LTCC), high-temperature co-fired ceramic (HTCC), direct plate copper (DPC), and direct bonded copper (DBC).

Currently, the most common ceramic heat-dissipating substrates for light-emitting diodes (LEDs) are prepared no longer from high-temperature co-fired ceramic (HTCC), which incurs a high production cost due to the high-temperature environment required for making HTCC heat-dissipating substrates, but from low-temperature co-fired ceramic (LTCC) instead. However, both LTCC and HTCC entail a thick-film forming process that is disadvantageous to the surface flatness of, and the fineness of the metal lines on, the resulting heat-dissipating substrates.

Recently, methods for preparing ceramic heat-dissipating substrates from direct plated copper (DPC) or direct bonded copper (DBC) substrates were developed to make heat-dissipating substrates for small and high-power LEDs. The DPC-substrate method is a thin-film forming process but still requires a costly high-temperature operating environment to achieve satisfactory attachment between the metal layer and the ceramic layer. The DBC-substrate method, on the other hand, uses vacuum sputtering to produce heat-dissipating substrates whose metal layer and ceramic layer are well bonded together, and which have higher surface flatness and finer metal lines than those achievable by the other three methods mentioned above.

### BRIEF SUMMARY OF THE INVENTION

While the DBC-substrate method overcomes the problem of high production cost associated with the high-temperature operation required in the HTCC method, the LTCC method, and the DPC-substrate method, the expensive vacuum sputtering equipment used in the DBC-substrate method may still add to the production cost of its ceramic heat-dissipating substrate products. Moreover, ceramic substrates are generally disadvantaged by their poor surface flatness, low metal-line fineness, and brittleness, which make it impossible to make ultra-thin ceramic substrates or subject ceramic substrates to such shaping processes as stamping.

The objective of the inventor of the present invention is to provide a method for making a metal-ceramic laminate heat-dissipating substrate, thereby overcoming the drawbacks of the conventional ceramic heat-dissipating substrates (such as high material cost, high production cost, and low bonding strength between metal lines and ceramic) and offering a thin and flexible heat-dissipating substrate that can effectively serve as the heat-dissipating substrate of an electronic product or device, in particular the heat-dissipating substrate of an LED.

In order to achieve the objective of the present invention as above, the present invention provides a method for making a metal-ceramic laminate heat-dissipating substrate, comprising the steps of: providing a metal base layer; forming a not-yet-sintered ceramic layer on a surface of the metal base layer; and forming a metal line on a surface of the not-yet-sintered ceramic layer, and then performing a sintering process.

Furthermore, the above method further comprises the steps of: before forming the not-yet-sintered ceramic layer on the surface of the metal base layer, boring the metal base layer to form a plurality of metal-walled through holes; filling the metal-walled through holes with the not-yet-sintered ceramic layer when the not-yet-sintered ceramic layer is formed on the surface of the metal base layer; and, once the sintering process is completed, boring the metal-walled through holes filled with the not-yet-sintered ceramic layer to form a plurality of through holes whose hole walls are formed by the sintered ceramic layer.

Furthermore, the not-yet-sintered ceramic layer is formed on the surface of the metal base layer by coating the surface of the metal base layer with a ceramic slurry.

Furthermore, the ceramic slurry has a viscosity ranging from 500 cps to 5000 cps.

Furthermore, the above method further comprises the step of forming a semi-solid ceramic slurry film by pre-baking, in order for the semi-solid ceramic slurry film to serve as the not-yet-sintered ceramic layer.

Furthermore, the semi-solid ceramic slurry film has a viscosity ranging from 5000 cps to 25000 cps.

Furthermore, the metal lines are formed by ink-jet printing, screen printing, planographic printing, laser metal deposition-based 3D printing or electron beam-based 3D printing.

Furthermore, the metal base layer is any one or a combination of at least two selected from a group consisting of aluminum, an aluminum alloy and a copper alloy.

Another object of the present invention is to provide an electronic device comprising the metal-ceramic laminate heat-dissipating substrate prepared by the above method.

Another object of the present invention is to provide a light-emitting diode comprising the metal-ceramic laminate heat-dissipating substrate prepared by the above method.

Comparing with the convention techniques, the present invention has the following advantages:

1. The method of the present invention for making a metal-ceramic laminate heat-dissipating substrate uses a metal base layer as the main body of the heat-dissipating substrate and produces a metal-ceramic composite material by coating the surface of the metal base layer with a ceramic layer. Compared with the conventional heat-dissipating substrates that include a ceramic main body, the heat-dissipating substrate disclosed herein has a flatter surface that contributes to finer metal lines. Moreover, unlike the conventional ceramic substrates, whose brittleness hinders further processing, the metal-ceramic laminate heat-dissipating substrate disclosed herein includes a metal base layer as its main body and therefore features a thin and flexible structure that can be shaped (e.g., by stamping) afterward. By providing the metal base layer as the main body of the metal-ceramic laminate heat-dissipating substrate, the use of ceramic, which is an expensive material, can also be reduced to lower the material cost of the substrate.

2. The method of the present invention for making a metal-ceramic laminate heat-dissipating substrate is carried out as follows. A ceramic layer that has yet to be sintered is formed on the surface of a metal base layer. Metal lines are then formed directly on the surface of the not-yet-sintered ceramic layer, before a sintering process is performed. The foregoing production process is simple, rapid, and therefore suitable for industrial application.

3. The method of the present invention for making a metal-ceramic laminate heat-dissipating substrate is so designed that, once the ceramic layer is formed on the surface of the metal base layer, the metal lines are formed directly on the surface of the ceramic layer and then sintered together with the ceramic layer. In other words, the metal lines and the ceramic layer are completed by being sintered at the same time. It follows that the resulting substrate has advantageously high bonding strength between the metal lines and the ceramic layer, meaning the metal lines are not prone to peeling off.

### BRIEF DESCRIPTION OF THE SEVERAL VIEWS OF THE DRAWINGS

FIG. 1 includes a series of sectional views that show the process flow of the method for making a metal-ceramic laminate heat-dissipating substrate according to the first embodiment of the present invention;

FIG. 2 is a sectional view of a metal-ceramic laminate heat-dissipating substrate made by the method shown in FIG. 1;

FIG. 3 includes a series of sectional views that show the process flow of the method for making a metal-ceramic laminate heat-dissipating substrate according to the second embodiment of the present invention; and

FIG. 4 is a sectional view of a metal-ceramic laminate heat-dissipating substrate made by the method shown in FIG. 3.

### DETAILED DESCRIPTION OF THE INVENTION

The details and technical solution of the present invention are hereunder described with reference to accompanying drawings. For illustrative sake, the accompanying drawings are not drawn to scale. The accompanying drawings and the scale thereof are not intended to be restrictive of the scope of the invention.

Throughout the whole document, the term “comprises or includes” and/or “comprising or including” used in the document means that one or more other components, steps, operations, and/or the existence or addition of elements are not excluded in addition to the described components, steps, operations and/or elements. The terms “a” and “an” refer to one or to more than one (i.e., to at least one) of the grammatical object of the article.

The method of the present invention for making a metal-ceramic laminate heat-dissipating substrate comprises the steps of: providing a metal base layer; forming a not-yet-sintered ceramic layer on a surface of the metal base layer; and forming a metal line on a surface of the not-yet-sintered ceramic layer, and then performing a sintering process. The surface of the metal base layer is not limited to the surface of a single side or two opposite sides of the metal base layer; the ceramic layer may cover the surface of the entire metal base layer. Similarly, the metal lines formed on the ceramic layer are not necessarily formed on the ceramic layer portion (or portions) on a single side or two opposite sides of the metal base layer; the metal lines may be distributed over the surface of the entire ceramic layer.

The method of the present invention for making a metal-ceramic laminate heat-dissipating substrate may further comprise the steps of: before forming the not-yet-sintered ceramic layer on the surface of the metal base layer, boring the metal base layer to form a plurality of metal-walled through holes; filling the metal-walled through holes with the not-yet-sintered ceramic layer when the not-yet-sintered ceramic layer is formed on the surface of the metal base layer; and, once the sintering process is completed, boring the metal-walled through holes filled with the not-yet-sintered ceramic layer to form a plurality of through holes whose hole walls are formed by the sintered ceramic layer.

As used herein, the term “metal base layer” refers to copper, aluminum, a copper alloy, or an aluminum alloy. A suitable copper alloy may be, but is not limited to, a copper-zinc alloy, a copper-tin alloy, a copper-aluminum alloy, a copper-silicon alloy, or a copper-nickel alloy; and a suitable aluminum alloy may be, but is not limited to, an aluminum-silicon alloy, an aluminum-magnesium-silicon alloy, an aluminum-copper alloy, an aluminum-magnesium alloy, an aluminum-manganese alloy, an aluminum-zinc alloy, or an aluminum-lithium alloy. Preferably, the metal base layer is aluminum, an aluminum alloy, or a copper alloy, although the metal of the metal base layer may be any one, or a combination of at least two, of the foregoing.

According to the method of the present invention, the not-yet-sintered ceramic layer is formed on the surface of the metal base layer by coating the surface of the metal base layer with a ceramic slurry, wherein the coating method employed may be, but is not limited to, spread coating, spray coating, print coating, or roller coating. Moreover, the ceramic slurry may be pre-baked to form a semi-solid ceramic slurry film as the not-yet-sintered ceramic layer.

The ceramic slurry used in the present invention is in a viscous state after being applied to the metal base layer. The ingredients of the ceramic slurry include ceramic powder, a solvent, a dispersant, a binder, a plasticizer, and so on. The ceramic powder essentially includes borosilicate-based glass powder and powder of any one, or a combination, of a metal oxide, a carbide, a nitride, a boride, and a silicide, such as silicon carbide (SiC), silicon nitride (Si₃N₄), aluminum nitride (AlN), alumina (Al₂O₃), titanium carbide (TiC), titanium boride (TiB₂), boron carbide (B₄C), lead zirconium titanate and manganese ferrite; the present invention has no limitation in this regard and allows any one, or a combination of at least two, of the foregoing to be used. The solvent and the dispersant may include water, an aliphatic hydrocarbon-based solvent, an alicyclic hydrocarbon-based solvent, an aromatic hydrocarbon-based solvent, a ketone-based solvent, an alcohol-based solvent, an ether-based solvent, and so on, some specific examples of which are hexane, decane, dodecane, tetradecane, cyclohexane, toluene, xylene, acetone, ethyl methyl ketone, methyl isobutyl ketone, methyl acetate, ethyl acetate, propyl acetate, butyl acetate, isobutyl acetate, propylene glycol methyl ether acetate, methanol, ethanol, n-propyl alcohol, isopropyl alcohol, n-butyl alcohol, ethylene glycol, diethylene glycol, triethylene glycol, propylene glycol, glycerol, tetrahydrofuran, ethylene glycol monomethyl ether, ethylene glycol monoethyl ether, ethylene glycol monobutyl ether, and 1-methoxy-2-propanol; the present invention has no limitation in this regard and allows any one, or a combination of at least two, of the foregoing to be used. As to the binder, some specific examples are vinyl alcohol, cationized starch, methyl cellulose, ethyl cellulose, poly(vinyl butyral), a (meth)acrylamide polymer, a (meth)acrylic acid polymer, an alkyl (meth)acrylate polymer, and a copolymer of (meth)acrylic acid and alkyl (meth)acrylate; the present invention has no limitation in this regard and allows any one, or a combination of at least two, of the foregoing to be used. The plasticizer may be dibutyl phthalate, an acid salt, a phosphate, an alcohol-ether plasticizer, a monoglyceride, a mineral oil, a polyester, a rosin derivative, a sebacate, a citrate, polyethylene glycol, dioctyl phthalate, a fatty acid, a polyalcohol, a fatty acid ester, a polyester-based plasticizer, or an epoxy-based plasticizer; the present invention has no limitation in this regard and allows any one, or a combination of at least two, of the foregoing to be used.

The ceramic slurry used in the present invention has a viscosity ranging from 200 cps to 7000 cps, preferably 500 cps to 5,000 cps, such as 500 cps, 600 cps, 700 cps, 800 cps, 900 cps, 1,000 cps, 1300 cps, 1500 cps, 1800 cps, 2,000 cps, 2300 cps, 2500 cps, 2800 cps, 3,000 cps, 3,300 cps, 3,500 cps, 3,800 cps, 4,000 cps, 4,300 cps, 4,500 cps, 4,800 cps, or 5,000 cps.

As used herein, the term “semi-solid ceramic slurry film” refers to that which is obtained by pre-baking the ceramic slurry used in the present invention and which therefore has the same ingredients as the ceramic slurry. The semi-solid ceramic slurry film has a viscosity ranging from 4000 cps to 28000 cps, preferably 5,000 cps to 25,000 cps, such as 5,000 cps, 8,000 cps, 10,000 cps, 13,000 cps, 15,000 cps, 18,000 cps, 20,000 cps, or 25,000 cps.

According to the method of the present invention, the metal lines are formed on the surface of the not-yet-sintered ceramic layer by printing metal powder (of which the metal lines are made) onto the surface of the ceramic layer, and this can be achieved by a conventional circuit printing method, such as ink-jet printing, screen printing, or planographic printing; or by a three-dimensional (3D) printing method for making a laminated object, such as laser metal deposition-based or electron beam-based 3D printing; the present invention has no limitation in this regard, although laser metal deposition-based or electron beam-based 3D printing is preferred. The metal powder may include a metal, an alloy, or a composite metal, such as but not limited to silver, copper, gold, aluminum, sodium, molybdenum, tungsten, zinc, nickel, iron, platinum, tin, lead, a silver-copper alloy, a cadmium-copper alloy, a chromium-copper alloy, a beryllium-copper alloy, a zirconium-copper alloy, an aluminum-magnesium-silicon alloy, an aluminum-magnesium alloy, an aluminum-magnesium-iron alloy, an aluminum-zirconium alloy, an iron-chromium-aluminum alloy, or a combination of at least two of the foregoing. Preferably, the metal powder is aluminum, gold, silver, or copper.

According to the method of the present invention, the sintering temperature is 200° C. to 2000° C., preferably 250° C. to 1400° C.; and the sintering time is about 10 to 40 minutes, preferably 20 to 30 minutes.

Once sintered, the ceramic layer in the present invention has a thickness ranging from 10 μm to 900 μm, preferably from 20 μm to 200 μm, more preferably from 30 μm to 50 μm, such as 30 μm, 35 μm, 40 μm, 45 μm, or 50 μm. The above thickness range provides the sintered ceramic layer with flexibility, a lower chance of cracking, and hence the ability to withstand the force of stamping when the resulting substrate is subjected to further processing.

Once sintered, the metal lines on the ceramic layer in the present invention have a thickness ranging from 0.5 μm to 40 μm, such as 0.5 μm, 1 μm, 5 μm, 10 μm, 15 μm, 20 μm, 25 μm, 30 μm, 35 μm, or 40 μm; and a line width equal to or greater than 0.5 μm. The metal lines may be distributed over the entire sintered ceramic layer.

A metal-ceramic laminate heat-dissipating substrate made by the method of the present invention can be used as the heat-dissipating substrate of various electronic devices, such as an LED, computer, smartphone, laptop computer, or loudspeaker, preferably an LED.

The present invention is described in more detail below with reference to specific embodiments. These embodiments, however, are not intended to be restrictive of the scope of the invention.

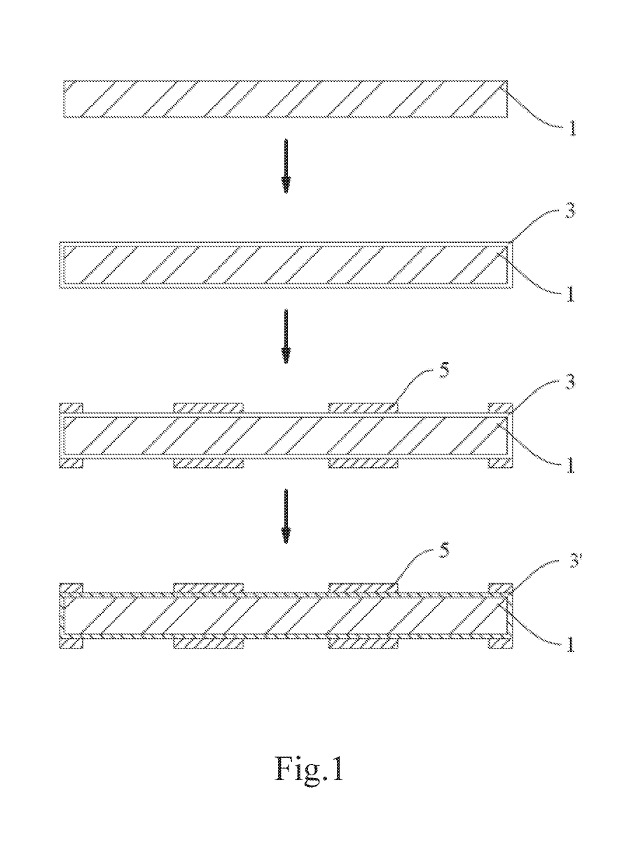

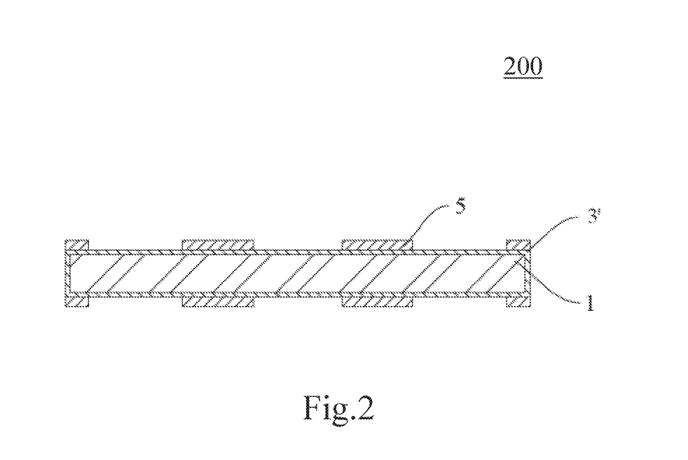

Please refer to FIG. 1 and FIG. 2 respectively for the process flow of the method for making a metal-ceramic laminate heat-dissipating substrate according to the first embodiment of the present invention and a metal-ceramic laminate heat-dissipating substrate thus made.

The method for making a metal-ceramic laminate heat-dissipating substrate according to this embodiment begins by providing a metal base layer 1. Then, the surface of the metal base layer 1 is coated with a ceramic slurry by thermal spraying in order to form a ceramic layer 3 that has yet to be sintered. This not-yet-sintered ceramic layer 3 is in a viscous state and has a viscosity of 600 cps. Next, metal lines 5 are printed on the not-yet-sintered ceramic layer 3 by a laser metal deposition-based 3D printing process, in which metal powder is deposited on the surface of the not-yet-sintered ceramic layer 3. After that, a sintering process is performed at 1000° C. for 25 minutes to form a sintered ceramic layer 3′ by sintering the not-yet-sintered ceramic layer 3, and to have the metal lines 5 attached completely to the sintered ceramic layer 3′ so that the metal lines 5 will not peel off easily, wherein each metal line 5 is 1 μm thick and 1 μm wide. Thus, a metal-ceramic laminate heat-dissipating substrate made according to the first embodiment is completed as shown in FIG. 2.

The metal-ceramic laminate heat-dissipating substrate 200 made according to the first embodiment can be further processed into a heat-dissipating substrate for LEDs, such as by providing the metal-ceramic laminate heat-dissipating substrate with barrier walls (e.g., through the use of adhesive or by stamping), in order for the barrier walls to form reflector cups (where LED chips can be subsequently mounted) and thereby turn the metal-ceramic laminate heat-dissipating substrate into a semi-finished LED strip.

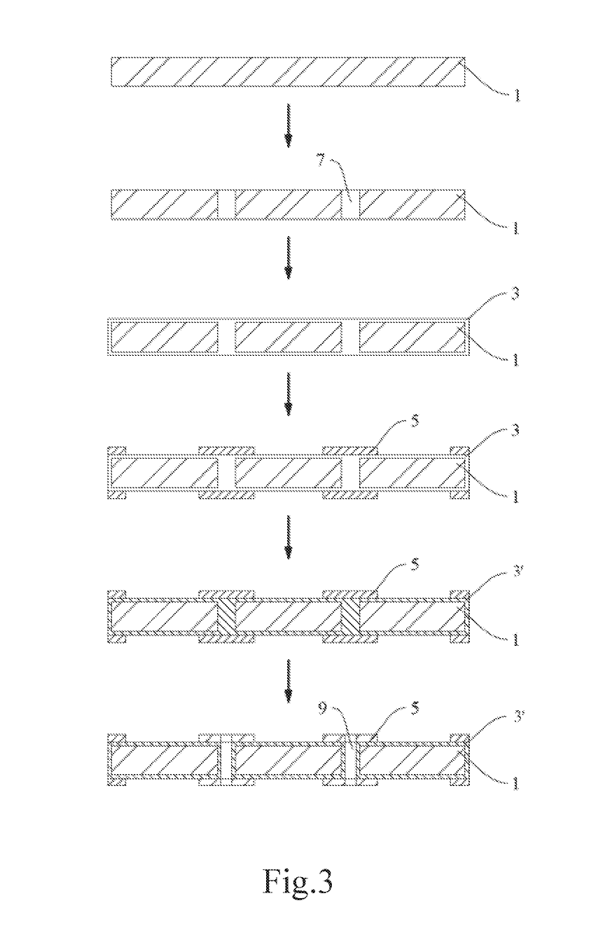

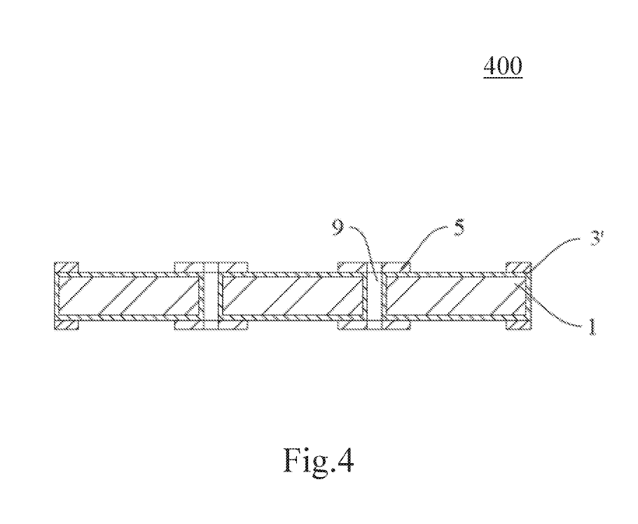

Please refer to FIG. 3 and FIG. 4 respectively for the process flow of the method for making a metal-ceramic laminate heat-dissipating substrate according to the second embodiment of the present invention and a metal-ceramic laminate heat-dissipating substrate thus made.

The method for making a metal-ceramic laminate heat-dissipating substrate according to this embodiment begins by providing a metal base layer 1. Then, the metal base layer 1 is bored to form a plurality of metal-walled through holes 7. Next, the surface of the metal base layer 1 is coated with a ceramic slurry by thermal spraying in order to form a ceramic layer 3 that has yet to be sintered. This not-yet-sintered ceramic layer 3 is in a viscous state and has a viscosity of 600 cps, and during the coating process, the metal-walled through holes 7 are filled up with the not-yet-sintered ceramic layer 3. Following that, metal lines 5 are printed on the not-yet-sintered ceramic layer 3 by a laser metal deposition-based 3D printing process, in which metal powder is deposited on the surface of the not-yet-sintered ceramic layer 3. Then, a sintering process is performed at 1000° C. for 25 minutes to form a sintered ceramic layer 3′ by sintering the not-yet-sintered ceramic layer 3, and to have the metal lines 5 attached completely to the sintered ceramic layer 3′ so that the metal lines 5 will not peel off easily, wherein each metal line 5 is 1 μm thick and 1 μm wide. After that, the metal-walled through holes 7 filled with the not-yet-sintered ceramic layer are bored to form a plurality of through holes 9, with the sintered ceramic layer 3′ forming the wall of each through hole 9. Thus, a metal-ceramic laminate heat-dissipating substrate made according to the second embodiment is completed as shown in FIG. 4.

The metal-ceramic laminate heat-dissipating substrate 400 made according to the second embodiment can be directly provided with LED chips to serve as their heat-dissipating substrate, or further processed into another type of heat-dissipating substrate for LEDs, such as by providing the metal-ceramic laminate heat-dissipating substrate with barrier walls (e.g., through the use of adhesive or by stamping), in order for the barrier walls to form reflector cups and thereby turn the metal-ceramic laminate heat-dissipating substrate into a semi-finished LED strip.

As above, the method of the present invention for making a metal-ceramic laminate heat-dissipating substrate uses a metal base layer as the main body of the heat-dissipating substrate and produces a metal-ceramic composite material by coating the surface of the metal base layer with a ceramic layer. Compared with the conventional heat-dissipating substrates that include a ceramic main body, the heat-dissipating substrate disclosed herein has a flatter surface that contributes to finer metal lines. Moreover, unlike the conventional ceramic substrates, whose brittleness hinders further processing, the metal-ceramic laminate heat-dissipating substrate disclosed herein includes a metal base layer as its main body and therefore features a thin and flexible structure that can be shaped (e.g., by stamping) afterward. By providing the metal base layer as the main body of the metal-ceramic laminate heat-dissipating substrate, the use of ceramic, which is an expensive material, can also be reduced to lower the material cost of the substrate. Next, the method of the present invention for making a metal-ceramic laminate heat-dissipating substrate is carried out as: a ceramic layer that has yet to be sintered is formed on the surface of a metal base layer; and, metal lines are then formed directly on the surface of the not-yet-sintered ceramic layer, before a sintering process is performed. Thus, the foregoing production process is simple, rapid, and therefore suitable for industrial application. Furthermore, the method of the present invention for making a metal-ceramic laminate heat-dissipating substrate is so designed that, once the ceramic layer is formed on the surface of the metal base layer, the metal lines are formed directly on the surface of the ceramic layer and then sintered together with the ceramic layer. In other words, the metal lines and the ceramic layer are completed by being sintered at the same time. It follows that the resulting substrate has advantageously high bonding strength between the metal lines and the ceramic layer, meaning the metal lines are not prone to peeling off.

What is claimed is:

1. A method for making a metal-ceramic laminate heat-dissipating substrate, comprising the steps of:
providing a metal base layer;
forming a not-yet-sintered ceramic layer on a surface of the metal base layer; and
forming a metal line on a surface of the not-yet-sintered ceramic layer, and then performing a sintering process.

2. The method of claim 1, further comprising the step of:
before forming the not-yet-sintered ceramic layer on the surface of the metal base layer, boring the metal base layer to form a plurality of metal-walled through holes;
filling the metal-walled through holes with the not-yet-sintered ceramic layer when the not-yet-sintered ceramic layer is formed on the surface of the metal base layer; and,
once the sintering process is completed, boring the metal-walled through holes filled with the not-yet-sintered ceramic layer to form a plurality of through holes whose hole walls are formed by the sintered ceramic layer.

3. The method of claim 1, wherein the not-yet-sintered ceramic layer is formed on the surface of the metal base layer by coating the surface of the metal base layer with a ceramic slurry.

4. The method of claim 2, wherein the not-yet-sintered ceramic layer is formed on the surface of the metal base layer by coating the surface of the metal base layer with a ceramic slurry.

5. The method of claim 3, wherein the ceramic slurry has a viscosity ranging from 500 cps to 5000 cps.

6. The method of claim 4, wherein the ceramic slurry has a viscosity ranging from 500 cps to 5000 cps.

7. The method of claim 3, further comprising the step of forming a semi-solid ceramic slurry film by pre-baking, in order for the semi-solid ceramic slurry film to serve as the not-yet-sintered ceramic layer.

8. The method of claim 4, further comprising the step of forming a semi-solid ceramic slurry film by pre-baking, in order for the semi-solid ceramic slurry film to serve as the not-yet-sintered ceramic layer.

9. The method of claim 7, wherein the semi-solid ceramic slurry film has a viscosity ranging from 5000 cps to 25000 cps.

10. The method of claim 8, wherein the semi-solid ceramic slurry film has a viscosity ranging from 5000 cps to 25000 cps.

11. The method of claim 1, wherein the metal lines are formed by ink-jet printing, screen printing, planographic printing, laser metal deposition-based 3D printing or electron beam-based 3D printing.

12. The method of claim 2, wherein the metal lines are formed by ink-jet printing, screen printing, planographic printing, laser metal deposition-based 3D printing or electron beam-based 3D printing.

13. The method of claim 1, wherein the metal base layer is any one or a combination of at least two selected from a group consisting of aluminum, an aluminum alloy and a copper alloy.

14. The method of claim 2, wherein the metal base layer is any one or a combination of at least two selected from a group consisting of aluminum, an aluminum alloy and a copper alloy.

15. An electronic device, comprising a metal-ceramic laminate heat-dissipating substrate prepared by the method of claim 1.

16. A light-emitting diode, comprising a metal-ceramic laminate heat-dissipating substrate prepared by the method of claim 1.
